(19) United States
(12) Patent Application Publication
(10) Pub. No.: US 2007/0205465 A1
(43) Pub. Date: Sep. 6, 2007

(54) Semiconductor device and fabrication method thereof

(76) Inventors: Hiroaki Yabu, Kyoto (JP); Toshihiro Kogami, Kyoto (JP); Katsuya Arai, Kyoto (JP)

Correspondence Address: MCDERMOTT WILL & EMERY LLP, 600 13TH STREET, NW, WASHINGTON, DC, 20005-3096, US

(21) Appl. No.: 11/706,335

(22) Filed: Feb. 15, 2007

(30) Foreign Application Priority Data
Mar. 2, 2006 (JP) 2006-056725

(51) Int. Cl. H01L 23/62; H01L 29/76; H01L 21/336

(52) U.S. Cl. 257/355; 257/382; 257/384; 438/682; 438/303

(57) ABSTRACT

A semiconductor device includes: a gate electrode on a semiconductor substrate; side wall spacers on side surfaces of the gate electrode; a source portion and a drain portion in the semiconductor substrate, the source portion and the drain portion being provided laterally to the side wall spacers; an on-source silicide film on the source portion; an on-drain silicide film on the drain portion; source contacts over the source portion; and at least a pair of drain contacts which are provided over the drain portion and which are aligned in the gate width direction of the gate electrode. Part of the drain portion between the pair of drain contacts includes a high resistance region at least in an area between the side wall spacer and edges of the drain contacts facing the gate electrode such that the on-drain silicide film is not provided in the high resistance region.

### BACKGROUND OF THE INVENTION

1. Field of the Invention

The present invention relates to a semiconductor device and a fabrication method thereof. More specifically, the present invention relates to an electrostatic discharge protection transistor having a silicide film.

2. Description of the Prior Art

In recent years, a MOS (Metal Oxide Semiconductor) device has been miniaturized. This leads to a shallower junction of the diffusion layer, which tends to cause an increase in parasitic capacitance. To prevent this, a silicide structure is widely used. Since the silicide structure has the property of reducing diffusion resistance, the parasitic capacitance can be reduced by using the silicide structure.

However, when a silicide film is formed over a plurality of device formation regions, a current may tend to flow between adjacent device formation regions. This causes current concentration on one point, which leads to thermal destruction. Such problem arises particularly where the silicide structure is applied to a device which is required to rapidly flow a large current, such as an electrostatic discharge protection transistor.

To cope with the problem, it has been proposed to form each electrostatic discharge protection transistor by subdivided transistors (in semiconductor moats) and to increase resistance between the adjacent electrostatic discharge protection transistors, such that current concentration is prevented (see, for example, the specification of U.S. Pat. No. 4,825,280).

Such electrostatic discharge protection transistor including subdivided transistors will be described below with reference to the drawings.

FIG. 13 is a plan view illustrating a conventional electrostatic discharge protection transistor 100 having a silicide film. FIGS. 14A through 14C are cross sections illustrating the electrostatic discharge protection transistor 100 of FIG. 13, wherein FIG. 14A is a cross section taken along the line XIIIa-XIIIa′ of FIG. 13, FIG. 14B is a cross section taken along the line XIIIb-XIIIb′ of FIG. 13, and FIG. 14C is a cross section taken along the line XIIIc-XIIIc′ of FIG. 13.

As shown in FIG. 13, the conventional electrostatic discharge protection transistor 100 has a plurality of (in this case, three) transistors 121 situated to share a common gate electrode 104. The transistors 121 are surrounded by a device isolation region 102 having an STI (Shallow Trench Isolation) structure which is a trench filled with an insulator. These three transistors 121 have a common cross sectional structure (shown in FIG. 14A). Adjacent two transistors 121 are isolated by the device isolation region 102 extending between sources and between drains (see FIGS. 14B and 14C) and are electrically connected under the gate electrode 104. That is, as shown in FIG. 14B, the device isolation region 102 extending between the sources and between the drains is not provided under the gate electrode 104. Moreover, each of the three transistors 121 has a drain contact 110D and a source contact 110S. The drain contacts 110D and the source contacts 110S of the three transistors 121 are respectively connected to a common metal wire 111D and a common metal wire 111S. From the foregoing, the structure including subdivided transistors is realized in the electrostatic discharge protection transistor 100, and the subdivided transistors serve as a transistor.

Next, as shown in FIG. 14A, the transistor 121 is formed by using a P-type semiconductor substrate 101 (not shown in FIG. 13) formed of silicon. The semiconductor substrate 101 is sectioned by the device isolation region 102. A gate insulation film 103 formed by a silicon oxide film, a gate electrode 104 formed of doped silicon on the gate insulation film 103, and an on-gate silicide film 105G on the gate electrode 104 are provided on an active region (not separately shown) of such sectioned semiconductor substrate 101.

Moreover, insulating side wall spacers 107 are provided on side surfaces of the gate insulation film 103, the gate electrode 104, and the on-gate silicide film 105G.

Part of the active region of the P-type semiconductor substrate 101 has N-type low concentration diffusion layers 106 provided under the side wall spacers 107. Moreover, part of the semiconductor substrate 101 includes an N-type high concentration drain portion 108D and an N-type high concentration source portion 108S, wherein the N-type high concentration drain portion 108D is provided laterally to one of the side wall spacers 107, and the N-type high concentration source portion 108S is provided laterally to the other side wall spacer 107. Moreover, an on-drain silicide film 105D and an on-source silicide film 105S are respectively provided on the N-type high concentration drain portion 108D and the N-type high concentration source portion 108S.

An interlayer insulation film 109 provided on the semiconductor substrate 101 covers the gate electrode 104, the drain portion 108D, the source portion 108S, and other components. Moreover, a drain contact 110D which reaches the on-drain silicide film 105D and a source contact 110S which reaches the on-source silicide film 105S are formed through the interlayer insulation film 109. Both the drain contact 110D and the source contact 110S are formed of Al or an Al alloy.

Moreover, the metal wire 111D and the metal wire 111S are respectively provided on the drain contact 110D and the source contact 110S. As shown in FIG. 13, the metal wire 111D is commonly and electrically connected to the drains of the three transistors 121. Likewise, the metal wire 111S is commonly and electrically connected to the sources of the three transistors 121 (see FIG. 13).

Moreover, an interlayer insulation film 112 provided on the interlayer insulation film 109 covers the metal wires 111D and 111S.

FIG. 14B is a cross section taken along the line XIIIb-XIIIb′ running between transistors 121. In FIG. 14B, the gate insulation film 103, the gate electrode 104, the on-gate silicide film 105G, and side wall spacers 107 are the same as those shown in FIG. 14A. However, in the cross section shown in FIG. 14B, the device isolation region 102 extends to both sides of the gate electrode 104 and isolates between the sources and between the drains of the adjacent transistors 121. The active region of the P-type semiconductor substrate 101 is provided below the gate insulation film 103, which provides an electrical connection for transistors 121.

Note that, the interlayer insulation film 109, the metal wires 111S and 111D on the interlayer insulation film 109, and the interlayer insulation film 112 have the same cross sections as those shown in FIG. 14A. In the cross section of FIG. 14B, the drain portion 108D and the source portion 108S do not exist. Of course, the source contact 110S and the drain contact 110D which respectively contact the source portion 108S and the drain portion 108D do not exist.

FIG. 14C is a cross section taken along the line XIIIc-XIIIc′ running across the three transistors 121. FIG. 14C shows that a surface of the P-type semiconductor substrate 101 is sectioned by the device isolation region 102, and the drain portions 108D and the on-drain silicide films 105D on the drain portions 108D are provided. Further, FIG. 14C shows the interlayer insulation films 109 covering the on-drain silicide films 105D and other components, the drain contacts 110D which are provided through the interlayer insulation film 109 and reach the on-drain silicide films 105D, the metal wire 111D connecting the drain contacts 110D, and the interlayer insulation film 112 on the metal wire 111D.

As described above, the three transistors 121 included in the electrostatic discharge protection transistor 100 are electrically connected with each other under the gate electrode 104 as shown in FIG. 14B. However, a drain portion 108D and an on-drain silicide film 105D on the drain portion 108D of a transistor 121 are isolated from a drain portion 108D and an on-drain silicide film 105D on the drain portion 108D of another transistor 121 by the device isolation region 102 as shown in FIGS. 13 and 14C. Likewise, a source portion 108S and an on-source silicide film 105S on the source portion 108S of a transistor 121 are isolated from a source portion 108S and an on-source silicide film 105S on the source portion 108S of another transistor 121. Therefore, a current mainly flows between the source contact 110S and the drain contact 110D which are situated to face each other with the gate electrode 104 interposed therebetween. In other words, a flow of current between the source of a transistor 121 and the drain of another transistor 121 is suppressed.

In this structure, transistors in the electrostatic discharge protection transistor 100 together operate as a transistor, and local current concentration is prevented.

However, the above-mentioned conventional electrostatic discharge protection transistor 100 has a problem as follows.

The conventional electrostatic discharge protection transistor 100 includes three transistors 121, which are transistors subdivided by the device isolation region 102. That is, the device isolation region 102 extends between the sources and between the drains. As a result, high stress occurs in regions in which transistors 121 are provided. This causes an increased leak current, which is a problem required to be solved.

### SUMMARY OF THE INVENTION

In view of the above-mentioned problems, an object of the present invention is to prevent the local current concentration and to reduce the stress so as to suppress the leak current in an integrated circuit having a silicide transistor.

A semiconductor device of the present invention includes: a gate electrode on a semiconductor substrate; side wall spacers on side surfaces of the gate electrode; a source portion and a drain portion in the semiconductor substrate, the source portion and the drain portion being provided laterally to the side wall spacers; an on-source silicide film on the source portion; an on-drain silicide film on the drain portion; at least a pair of source contacts which are provided over the source portion such that the on-source silicide film is interposed between the source portion and the pair of source contacts and which are aligned in the gate width direction of the gate electrode; and at least a pair of drain contacts which are provided over the drain portion such that the on-drain silicide film is interposed between the drain portion and the pair of drain contacts and which are aligned in the gate width direction of the gate electrode, wherein part of the drain portion between the pair of drain contacts includes a high resistance region at least in an area between the side wall spacer and edges of the drain contacts facing the gate electrode such that the on-drain silicide film is not provided in the high resistance region.

According to the semiconductor device of the present invention, the transistor includes silicide films on the source portion and drain portion (the on-source silicide film and the on-drain silicide film), at least a pair of source contacts, and at least a pair of drain contacts, wherein an area without the silicide film is provided on the drain portion.

Electrical resistance of the silicide films is lower than that of the drain portion. Therefore, the area without the silicide film (the area in which the silicide film is not provided) is a high resistance region having a resistance higher than that of an area in which the silicide film is provided. As a result, a current tends to avoid the high resistance region and flow through the area having the silicide film.

Part of the drain portion between adjacent (pairs of) drain contacts includes such high resistance region at least in an area between the side wall spacer and edges of the drain contacts facing the gate electrode. In other words, the high resistance region is provided in at least one of parts between the gate electrode and areas which are situated between pairs of adjacent drain contacts.

As a result, a current taking path avoiding the high resistance region more likely flows between a source contact and a drain contact which are situated in pairs to face each other with the gate electrode interposed therebetween. In other words, the high resistance region suppresses a flow of current from a source contact to the other drain contacts which do not face the source contact with the gate electrode interposed therebetween.

Therefore, the local current concentration, such as a flow of current from a plurality of source contacts to a drain contact, is suppressed. Since the silicide film is provided but the high resistance region is not provided in areas between each drain contact and the gate electrode, a flow of current between a source contact and a drain contact which are situated to face each other with the electrode interposed therebetween is not disturbed.

In this case, according to the semiconductor substrate of the present invention, the transistor is planarly surrounded by the device isolation region. However, compared to the semiconductor device according to the conventional technique having subdivided transistors, the stress caused by the device isolation region is reduced.

That is, the conventional semiconductor device has a structure including subdivided transistors in order to avoid the local current concentration. To form the structure, the device isolation region is formed such that the device isolation region extends between the source contacts and between the drain contacts. As a result, the device isolation region causes high stress, which leads to an increased leak current.

Compared to this, in the semiconductor device of the present invention, the transistor is only surrounded by the device isolation region. Therefore, the stress caused by the device isolation region is smaller compared to the conventional technique. The leak current caused by the stress is suppressed.

It is preferable that the high resistance region extends into an area between the drain contacts.

In this structure, a flow of current between the adjacent drain contacts is suppressed, so that the local current concentration is more certainly suppressed.

Moreover, the on-source silicide film is provided over the whole surface of the source portion. Generally, an electric field in the source portion is lower than an electric field in the drain portion, so that, the current concentration occurs less likely in the source portion than in the drain portion. Therefore, it is possible to obtain the effect of suppressing the current concentration by providing the high resistance region without the silicide film at least in the drain portion.

It is preferable that part of the source portion between the pair of source contacts includes another high resistance region at least in an area between the side wall spacer and edges of the source contacts facing the gate electrode such that the on-source silicide film is not provided in said another high resistance region.

As mentioned above, the current concentration less likely occurs in the source portion than in the drain portion. However, the current concentration can occur also in the source portion. Therefore, providing the high resistance region not only in the drain portion, but also in the source portion enables more certain prevention of the current concentration. For this purpose, it is preferable that the high resistance region is provided in the above-mentioned area in which the high resistance region does not interrupt a flow of current between a source contact and a drain contact which are situated to face each other with the gate electrode interposed therebetween, but can suppress a flow of current between other combinations of source contacts and drain contacts.

Moreover, it is preferable that said another high resistance region extends into an area between the source contacts.

In this structure, a flow of current between adjacent source contacts is suppressed, and thus the local current concentration is more certainly suppressed.

Moreover, it is preferable that an on-gate silicide film is provided on the gate electrode, wherein the gate electrode includes an on-gate high resistance region in a part planarly continuing from the high resistance region such that the on-gate silicide film is not provided in the on-gate high resistance region.

Moreover, it is preferable that an on-gate silicide film is provided on the gate electrode, wherein the gate electrode includes an on-gate high resistance region in a part planarly continuing from said another high resistance region such that the on-gate silicide film is not provided in the on-gate high resistance region.

The high resistance region provided in such an area enables more certain avoidance of the local current concentration because it is possible to certainly form a structure which does not include an area having a silicide film between the side wall spacer and the high resistance region.

It is preferable that a protection film is provided on the high resistance region. Such structure is preferable, because the protection film assures the formation of the high resistance region in which the silicide film is not formed.

A fabrication method of a semiconductor device of the present invention includes the steps of: (a) forming a gate electrode on a semiconductor substrate; (b) forming side wall spacers on side surfaces of the gate electrode; (c) forming a source portion and a drain portion in the semiconductor substrate such that the source portion and the drain portion are provided laterally to the side wall spacers; (d) forming an on-source silicide film on the source portion, and forming an on-drain silicide film on the drain portion; and (e) forming at least a pair of source contacts over the source portion such that the on-source silicide film is provided between the source portion and the pair of source contacts and that the pair of source contacts are aligned in the gate width direction of the gate electrode, and forming at least a pair of drain contacts over the drain portion such that the on-drain silicide film is provided between the drain portion and the pair of drain contacts and that the pair of drain contacts are aligned in the gate width direction of the gate electrode, wherein in step (d), in part of the drain portion between the pair of drain contacts, a high resistance region is formed at least in an area between the side wall spacer and edges of the drain contacts facing the gate electrode such that the on-drain silicide film is not provided in the high resistance region.

According to the above-mentioned fabrication method of a semiconductor device, it is possible to fabricate the semiconductor device of the present invention in which the local current concentration is eliminated by the high resistance region having a resistance higher than that of areas in which silicide films (on-source silicide film and on-drain silicide film) are formed, and at the same time, stress is reduced such that the leak current is reduced.

It is preferable that the method further includes after step (c) and before the step (d), forming a protection film on an area of the drain portion which is to be the high resistance region, wherein in step (d), the protection film prevents formation of the on-drain silicide film such that the high resistance region is formed.

In this method, the high resistance region without the silicide film is realized by providing the protection film to prevent the formation of the silicide film.

Moreover, it is preferable that step (d) includes forming an on-gate silicide film on the gate electrode; and forming the protection film in an area which planarly and continuously straddles from the drain portion to the gate electrode such that the high resistance region is formed in the area which planarly and continuously straddles from the drain portion to the gate electrode.

According to the above-mentioned method, it is possible to form the high resistance region without leaving an area in which the on-drain silicide film is formed between the high resistance region in the drain portion and the gate electrode even in a case where misalignment occurs in forming the protection film. As a result, it is possible to fabricate a semiconductor device in which the current concentration can be more certainly prevented.

Alternatively, it is preferable that step (d) includes forming a metal film on the semiconductor substrate to cover the source portion and drain portion; removing the metal film in an area of the drain portion which is to be the high resistance region; and performing a thermal treatment to form the on-source silicide film and the on-drain silicide film such that silicidation is prevented in the area which is to be the high resistance region.

The metal film to be used for forming the silicide film is removed from an area which is to be the high resistance region, such that that the formation of the silicide film is prevented in the area from which the metal film has been removed. In this way, the high resistance region which does not have the silicide film can be formed.

Moreover, it is preferable that step (d) includes forming an on-gate silicide film on the gate electrode; removing the metal film from an area which planarly and continuously straddles from the drain portion to the gate electrode such that the high resistance region is formed in the area which planarly and continuously straddles from the drain portion to the gate electrode.

According to the above-mentioned method, it is possible to form the high resistance region without leaving an area in which the on-drain silicide film is formed between the high resistance region in the drain portion and the gate electrode even in a case where the area from which the metal film is to be removed is out of alignment. As a result, it is possible to fabricate a semiconductor device in which the current concentration can be more certainly prevented.

It is preferable that a part in which the formation of the silicide film is prevented so as to be the high resistance region, that is, the part in which the protection film is formed or the part in which the metal film is removed is not only in the above-mentioned area, but also extends into an area between the drain contacts. Moreover, it is preferable that the part in which the formation of the silicide film is prevented is provided in at least one of parts between the gate electrode and areas which are situated between pairs of source contacts. Furthermore, it is preferable that the part in which the formation of the silicide film is prevented extends into an area between the source contacts. In this way, it is possible to fabricate a semiconductor device in which the current concentration can be more certainly suppressed.

As described so far, according to the semiconductor device of the present invention, in each transistor including source contacts, drain contacts and a silicide film, it is possible to suppress an increase in leak current due to the stress caused by the device isolation region, and at the same time, it is possible to eliminate the local current concentration. Moreover, according to the present invention, it is possible to fabricate such semiconductor device.

### BRIEF DESCRIPTION OF THE DRAWINGS

FIG. 1 is a plan view illustrating a structure of an electrostatic discharge protection transistor 50 of Embodiment 1 of the present invention.

FIGS. 2A through 2D are cross sections of the electrostatic discharge protection transistor 50 whose plan view is shown in FIG. 1, wherein FIG. 2A is a cross section taken along the line Ia-Ia′ of FIG. 1, FIG. 2B is a cross section taken along the line Ib-Ib′ of FIG. 1, FIG. 2C is a cross section taken along the line Ic-Ic′ of FIG. 1, and FIG. 2D is a cross section taken along the line Id-Id′ of FIG. 1.

FIGS. 3A through 3E are cross sections with which a fabrication method of a semiconductor device of Embodiment 1 is explained.

FIGS. 4A through 4D are cross sections with which a variation of the fabrication method of the semiconductor device of Embodiment 1.

FIG. 5 is a plan view illustrating a structure of an electrostatic discharge protection transistor 50a of Embodiment 2 of the present invention.

FIGS. 6A and 6B are cross sections of the electrostatic discharge protection transistor 50a whose plan view is shown in FIG. 5, wherein FIG. 6A is a cross section taken along the line Vb-Vb′ of FIG. 5, and FIG. 6B is a cross section taken along the line Vc-Vc′ of FIG. 5.

FIG. 7 is a plan view illustrating a structure of an electrostatic discharge protection transistor 50b of Embodiment 3 of the present invention.

FIG. 8 is a cross section taken along the line VIIb-VIIb′ of the electrostatic discharge protection transistor 50b whose plan view is shown in FIG. 7.

FIG. 9 is a plan view illustrating a structure of an electrostatic discharge protection transistor 50c of Embodiment 4 of the present invention.

FIG. 10 is a cross section taken along the line IXb-IXb′ of the electrostatic discharge protection transistor 50c whose plan view is shown in FIG. 9.

FIG. 11 is a plan view illustrating a structure of an electrostatic discharge protection transistor 50d of Embodiment 5 of the present invention.

FIG. 12 is a cross section taken along the line XIb-XIb′ of the electrostatic discharge protection transistor 50d whose plan view is shown in FIG. 11.

FIG. 13 is a plan view illustrating a structure of a conventional electrostatic discharge protection transistor 100.

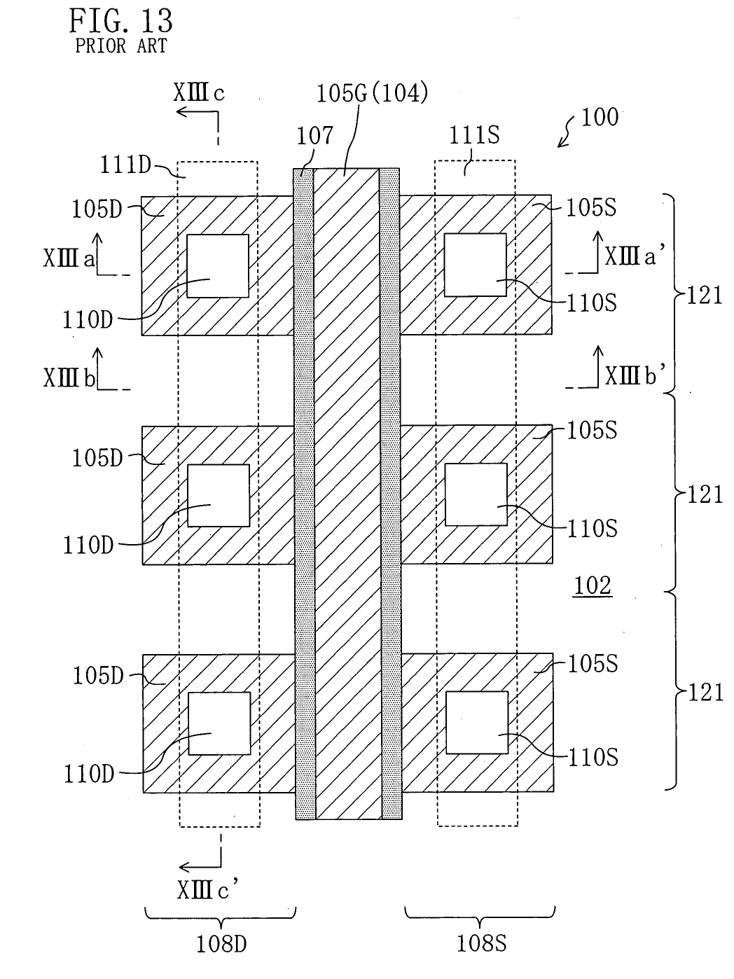

FIGS. 14A through 14C are cross sections of the conventional electrostatic discharge protection transistor 100 whose plan view is shown in FIG. 13, wherein FIG. 14A is a cross section taken along the line XIIIa-XIIIa′ of FIG. 13, FIG. 14B is a cross section taken along the line XIIIb-XIIIb′ of FIG. 13, and FIG. 14C is a cross section taken along the line XIIIc-XIIIc′ of FIG. 13.

### DESCRIPTION OF THE PREFERRED EMBODIMENTS

A semiconductor device and a fabrication method thereof according to Embodiment 1 of the present invention will be described below with reference to the drawings.

### Embodiment 1

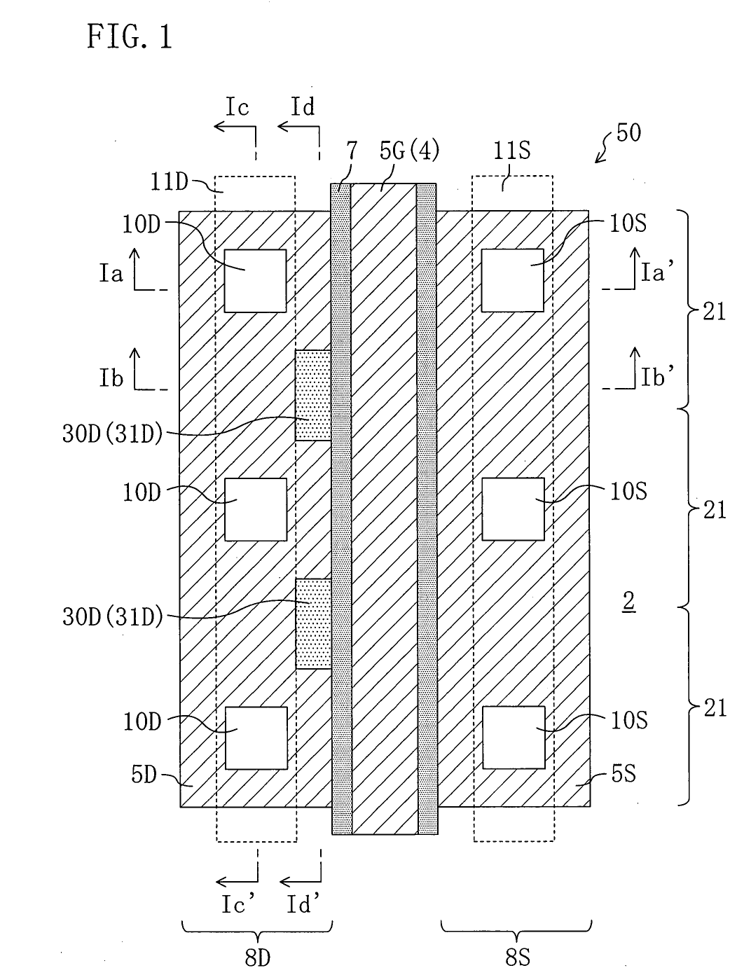

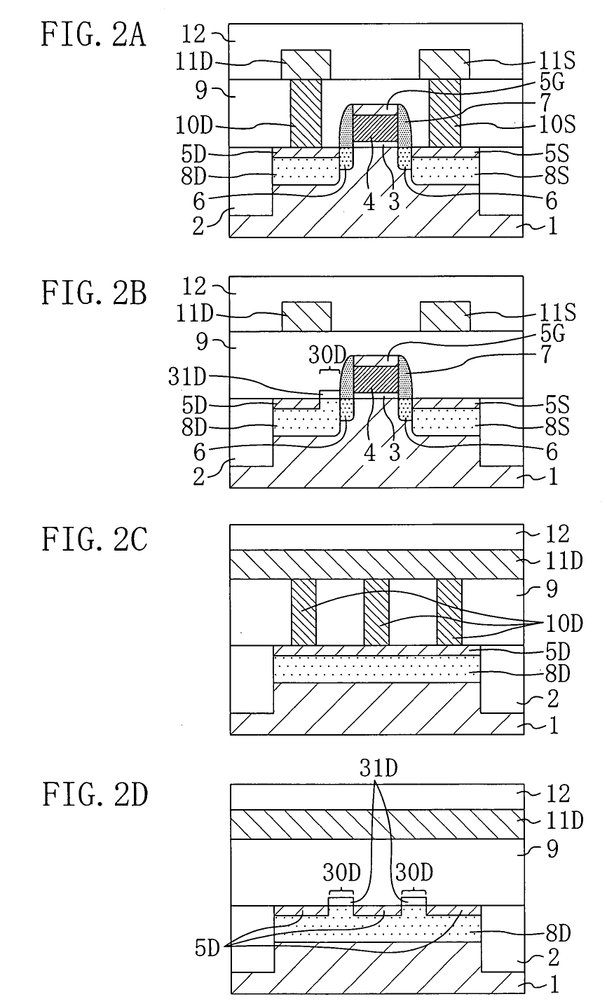

FIG. 1 is a plan view illustrating a structure of an electrostatic discharge protection transistor 50 of Embodiment 1. Note that, illustration of some of components is omitted. FIGS. 2A through 2D are cross sections illustrating the electrostatic discharge protection transistor 50, wherein FIG. 2A is a cross section taken along the line Ia-Ia′ of FIG. 1, FIG. 2B is a cross section taken along the line Ib-Ib′ of FIG. 1, FIG. 2C is a cross section taken along the line Ic-Ic′ of FIG. 1, and FIG. 2D is a cross section taken along the line Id-Id′ of FIG. 1.

As shown in FIG. 1, the electrostatic discharge protection transistor 50 is surrounded by a device isolation region 2 having an STI structure and has a plurality of (in this case, three) transistor structures 21 situated to share a common gate electrode 4. The transistor structures 21 together serve as a transistor. In this case, in a semiconductor substrate 1 (not shown in FIG. 1) formed of silicon, the device isolation region 2 is provided as shown in, for example, FIG. 2A. In other words, the electrostatic discharge protection transistor 50 includes three drain contacts 10D and three source contacts 10S. High resistance regions 30D, which will be explained in detail later, are provided on a drain portion 8D.

The three transistor structures 21, each of which including the drain contact 10D, the source contact 10S, and other components, have the same cross sectional structure. Therefore, a cross sectional structure of one of the transistor structures 21 is representatively shown in FIG. 2A.

The semiconductor substrate 1 is P-type, formed of a doped silicon, and sectioned by the device isolation region 2 which surrounds the semiconductor substrate 1. On an active region (not shown) of the semiconductor substrate 1, a gate insulation film 3 formed by, for example, a silicon oxide film or a silicon nitride film is provided. On the gate insulation film 3, the gate electrode 4 is provided. On the gate electrode 4, an on-gate silicide film 5G is provided. On side surfaces of the gate insulation film 3 and the gate electrode 4, insulating side wall spacers 7 are provided.

The active region of the semiconductor substrate 1 includes N-type low concentration diffusion layers 6 under the side wall spacers 7. The N-type low concentration diffusion layers 6 are to be LLD regions or extension regions. The active region of the semiconductor substrate 1 includes the drain portion 8D which is N-type and has a high concentration and a source portion 8S which is N-type and has a high concentration, wherein the drain portion 8D is provided laterally to one of the side wall spacers 7 on the gate electrode 4, and the source portion 8S is provided laterally to the other side wall spacer 7 on the gate electrode 4. Furthermore, an on-drain silicide film 5D is provided on the drain portion 8D, and an on-source silicide film 5S is provided on the source portion 8S. The concentration of an impurity implanted in the drain portion 8D (for example, 1×10²⁰ atoms/cm³) is higher than that in the low concentration diffusion layers 6 (for example, 5×10¹⁷ atoms/cm³). It is preferable that a cobalt silicide film, a nickel silicide film, or the like is used as the on-gate silicide film 5G, the on-drain silicide film 5D, and the on-source silicide film 5S.

An interlayer insulation film 9 on the semiconductor substrate 1 covers the gate electrode 4, the drain portion 8D, the source portion 8S, and other components. The drain contact 10D and the source contact 10S penetrate through the interlayer insulation film 9 and respectively reach the on-drain silicide film 5D and the on-source silicide film 5S. Both the drain contact 10D and the source contact 10S are formed of Ti/TiN and tungsten (W).

Moreover, a metal wire 11D and a metal wire 11S both of which are formed of Al or an Al alloy are respectively provided on the drain contact 10D and the source contact 10S. As indicated by dashed lines in FIG. 1, the metal wire 11D is a wire for commonly connecting the drain contacts 10D of the three transistor structures 21. Likewise, the metal wire 11S is a wire for commonly connecting the source contacts 10S of the three transistor structures 21.

An interlayer insulation film 12 provided on the interlayer insulation film 9 covers the metal wires 11D and 11S.

Next, the high resistance regions provided in the electrostatic discharge protection transistor 50 of the present invention will be explained. In a transistor having a silicide film, one of functions of the silicide film is to reduce resistance on a surface of a drain portion or a source portion. Therefore, an area in which the silicide film is not provided (the area without silicide film) has a higher resistance than an area in which the silicide film is provided.

As shown in FIG. 1, in the electrostatic discharge protection transistor 50, the drain portion 8D includes protection films 31D each of which is provided in an area between the gate electrode 4 and an area which is situated between (a pair of) adjacent drain contacts 10D. Since the on-drain silicide film 5D is not formed in the area of the drain portion 8D in which area the protection film 31D is provided, the area is the high resistance region 30D having a higher resistance than other areas in which the on-drain silicide film 5D is provided.

FIG. 2B is a cross section taken along the line Ib-Ib′ running between transistor structures 21 through the high resistance region 30D of FIG. 1. According to Embodiment 1, as shown in FIG. 2B, the protection film 31D is provided on the drain portion 8D such that the formation of the on-drain silicide film 5D is prevented in the area of the drain portion 8D in which area the protection film 31D is provided. Therefore, the high resistance region 30D without the on-drain silicide film 5D is provided in the drain portion 8D. A fabrication method of such structure will be further explained later.

A structure in FIG. 2B is different from the structure of FIG. 2A in that the drain contact 10D and the source contact 10S are not provided. Moreover, the structure in FIG. 2B is different from the structure of FIG. 2A in that the protection film 31D which is provided on the drain portion 8D and on a side of the side wall spacer 7 forms the high resistance region 30D, and the on-drain silicide film 5D is not provided under the high resistance region 30D. Other components being the same as those shown in FIG. 2A are given the same reference numerals as in FIG. 2A to omit the detailed description thereof.

FIG. 2C is a cross section taken along the line Ic-Ic′ running through the metal wire 11D connected to the drain contacts 10D of FIG. 1. FIG. 2D is a cross section taken along the line Id-Id′ running through the high resistance regions 30D along the gate electrode 4 of FIG. 1.

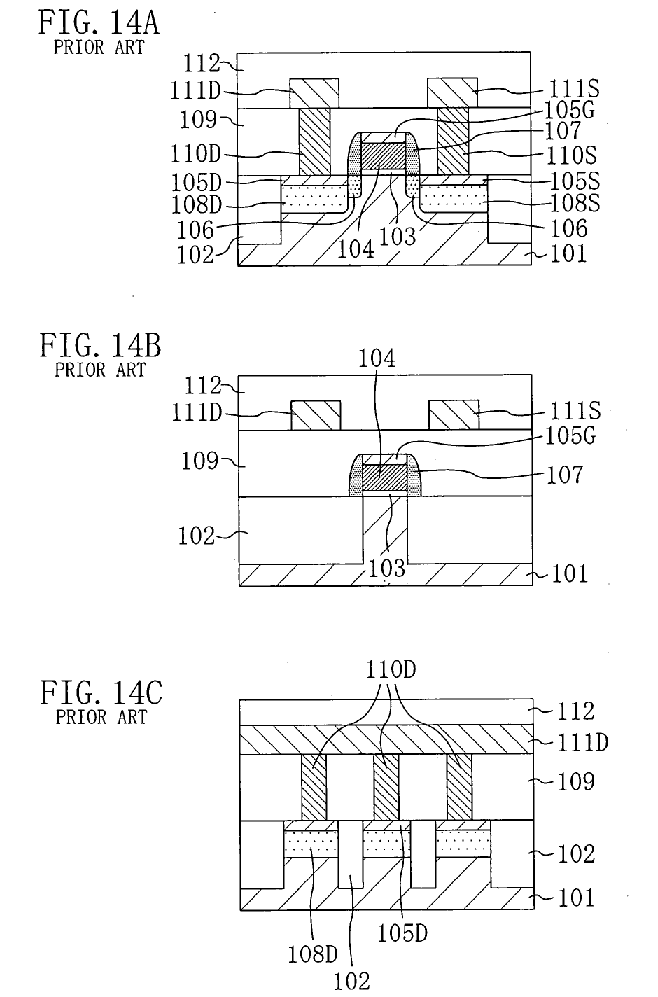

As shown in FIGS. 2C and 2D, the electrostatic discharge protection transistor 50 has the drain portion 8D which is continuously formed for the three transistor structures 21. This is one of differences between Embodiment 1 and the conventional electrostatic discharge protection transistor 100 shown in the cross section of FIG. 14B where three drain portions are isolated from each other by the device isolation region. This is also seen by comparing the cross section taken along the line running between the transistors 212 of the conventional electrostatic discharge protection transistor 100 of FIG. 14B and the cross section taken along the line running between the transistors 21 of the electrostatic discharge protection transistor 50 of FIG. 2B.

The device isolation region 2 planarly surrounds the electrostatic discharge protection transistor 50 so as to isolate the electrostatic discharge protection transistor 50 from other areas on the semiconductor substrate 1. This structure is the same as that of the conventional device.

As can be seen in the conventional electrostatic discharge protection transistor 100, the on-drain silicide film 105D is interrupted by the device isolation region 102 situated between the drain contacts 110D. Compared to this, in the electrostatic discharge protection transistor 50 of Embodiment 1, three drain contacts 10D are provided over the drain portion 8D. Also between the drain contacts 10D, the on-drain silicide film 5D is provided on the drain portion 8D.

According to the above-mentioned structure of the electrostatic discharge protection transistor 50 of Embodiment 1, it is possible to prevent the local current concentration, and at the same time, it is possible to reduces the stress more than the conventional structure reduces it, so that the leak current is reduced. This will be explained below.

As explained above, the high resistance region 30D in which the on-drain silicide film 5D is not provided has a higher resistance than an area in which the on-drain silicide film 5D is provided. Therefore, the high resistance region 30D hardly conducts a current. In other words, a current tends to take paths avoiding the high resistance region 30D.

In this case, considering the arrangement in the gate width direction of the gate electrode 4, the high resistance region 30D is provided in an area between (a pair of) adjacent drain contacts 10D. Considering the arrangement in a direction orthogonal to the gate width direction, that is, in the gate length direction of the gate electrode 4, the high resistance region 30D is situated between the gate electrode 4 and the drain contacts 10D.

The high resistance region 30D provided in such an area does not disturb a flow of current between a source contact 10S and a drain contact 10D which are situated to face each other with the gate electrode 4 interposed therebetween. Meanwhile, a flow of current between a source contact 10S and a drain contact 10D which do not face each other with the gate electrode 4 interposed therebetween is suppressed by the high resistance region 30D. That is, a flow of current from a source contact 10S of a transistor structure 21 to a drain contact 10D of another (for example, adjacent) transistor structure 21 is suppressed.

Since an electric field is generally higher in a drain portion than an electric field of a source portion, the current concentration more likely occurs in the drain portion than in the source portion. Therefore, providing the high resistance region 30D in the drain portion 8D can effectively suppress the current concentration.

The conventional electrostatic discharge protection transistor 100 has the device isolation region 102 extending between the transistors 121. A problem of such structure is that the device isolation region 102 causes high stress, which leads to the leak current. In Embodiment 1, the device isolation region 2 planarly surrounds the electrostatic discharge protection transistor 50, but does not extend, for example, between the drain contacts 10D. Therefore, the stress caused by the device isolation region 2 in Embodiment 1 is lower than that in the conventional device, so that the leak current is reduced.

As shown in FIG. 1, in the electrostatic discharge protection transistor 50 of Embodiment 1, each high resistance region 30D is planarly in contact with the side wall spacer 7 on a side surface of the gate electrode 4. That is, an area having the on-drain silicide film 5D does not exist between the high resistance region 30D and the gate electrode 4. Such structure is preferable to suppress the current concentration. However, the current concentration can be suppressed even in a case where the area having the on-drain silicide film 5D exists between the gate electrode 4 and the high resistance region 30D.

In the electrostatic discharge protection transistor 50, the high resistance region 30D is provided in every area (in this case, in both of two areas) between drain contacts 10D adjacent in the gate width direction. This structure is preferable to certainly suppress the current concentration. However, providing the high resistance region 30D at least in one of such areas can suppress the current concentration.

Fabrication Method of Semiconductor Device

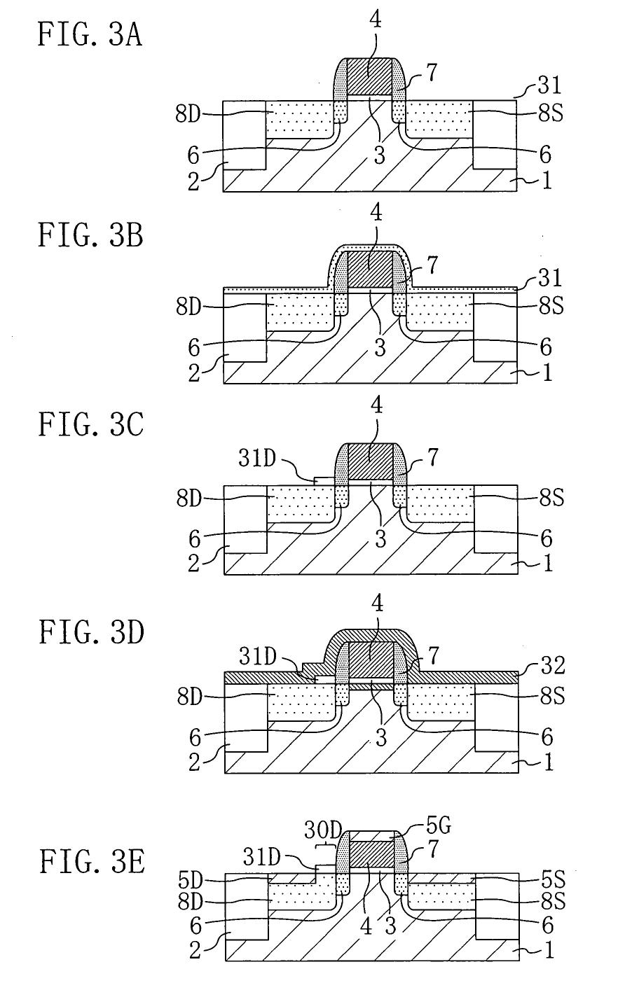

A fabrication method of the electrostatic discharge protection transistor 50, specifically a formation method of the high resistance region 30D will be explained below with reference to the drawings. FIGS. 3A through 3E are cross sections taken along the line Ib-Ib′ of FIG. 1 (that is, the same cross sections as those shown in FIG. 2B) with which formation steps of the electrostatic discharge protection transistor 50 will be explained.

First, as shown in FIG. 3A, on an active region of a semiconductor substrate 1 sectioned by a device isolation region 2, a gate insulation film 3, a gate electrode 4, side wall spacers 7, and other components are provided. These components are formed by known techniques such as photolithography and etching. Moreover, in FIG. 3A, formation of N-type low concentration diffusion layers 6, a drain portion 8D, and a source portion 8S has been completed by implanting (for example, by ion implantation of) an N-type impurity such as arsenic (As) or phosphor (P) in predetermined portions in the semiconductor substrate 1.

Next, referring to FIG. 3B, a silicon oxide film is formed by, for example, CVD to cover the semiconductor substrate 1. The silicon oxide film is referred to as a protection film 31.

Subsequently, referring to FIG. 3C, the protection film 31 is selectively removed such that the protection film 31 remains in areas corresponding to the high resistance regions 30D shown in FIG. 1. In this way, the protection film 31D which is to be used to form the high resistance regions 30D is formed. To form the protection film 31D, techniques such as photolithography and etching may be used.

After that, referring to FIG. 3D, a metal film, in this case, a cobalt film 32 is formed to cover the semiconductor substrate 1. Further, a thermal treatment is performed to form an on-drain silicide film 5D, an on-source silicide film 5S, and an on-gate silicide film 5G as shown in FIG. 3E. In this case, an area of the drain portion 8D having the protection film 31D is not silicidized, so that the on-drain silicide film 5D is not formed in this area. As a result, the unsilicidized drain portion 8D is situated under the protection film 31. Note that, the metal film is not limited to the cobalt film, but other metal films such as a nickel film may be used.

Then, in order to obtain the structure shown in FIGS. 2A through 2D, an interlayer insulation film 9 is formed on the semiconductor substrate 1, and a plurality of contact holes which respectively reach the on-drain silicide film 5D and the on-source silicide film 5S are formed. Further, a conductive material is filled in the contact holes to form drain contacts 10D and source contacts 10S.

Moreover, a metal wire 11D which connects the drain contacts 10D and a metal wire 11S which connects the source contacts 10S are formed. Then, an interlayer insulation film 12 is formed on the interlayer insulation film 9 to cover these metal wires 11D and 11S.

Note that, the drain contacts 10D, the source contacts 10S, and the metal wires 11D and 11S may be formed by a so-called dual-damascene method including the steps of forming contact holes and wire trenches in an interlayer insulation film, filling Cu films in the contact holes and the wire trenches, and then polishing the surfaces thereof.

In this way, it is possible to fabricate the electrostatic discharge protection transistor 50 of Embodiment 1 having the high resistance region 30D in the drain portion 8D. Note that, after the step illustrated with reference to FIG. 3E, the protection film 31D may remain as in Embodiment 1, or may be removed by etching before the interlayer insulation film 9 is formed. With or without the protection film 31D, it is possible to produce the effect of avoiding the current concentration by providing the high resistance regions 30D without the on-drain silicide films 5D in the areas as shown in FIG. 1.

### Variations of Embodiment 1

Another fabrication method of the electrostatic discharge protection transistor 50 of Embodiment 1 will be explained as a variation.

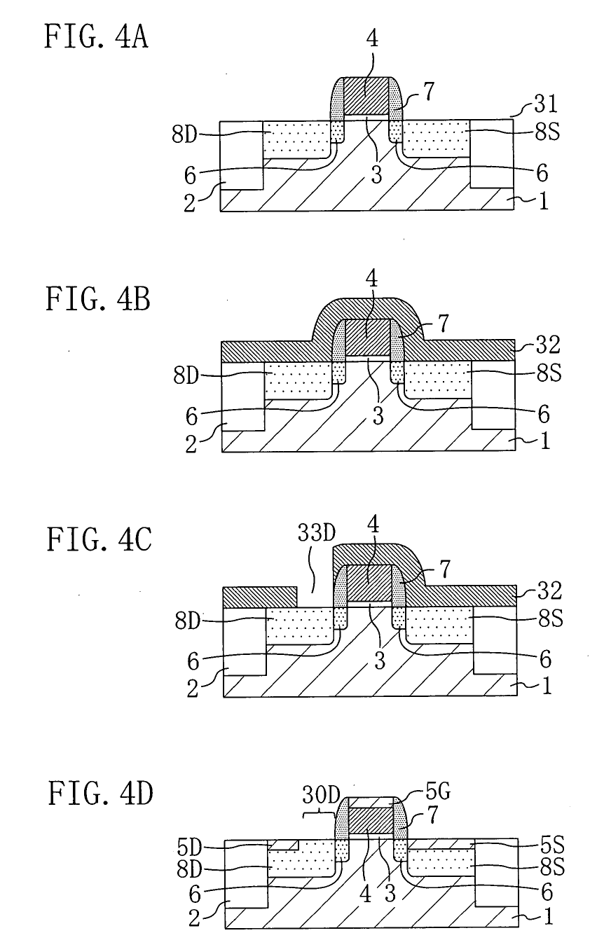

With reference to FIGS. 4A through 4D, another method for providing the high resistance region 30D as well as the electrostatic discharge protection transistor 50 will be explained. As FIGS. 3A through 3E, FIGS. 4A through 4D are cross sections taken along the line Ib-Ib′ of FIG. 1.

FIG. 4A is the same as FIG. 3A. In FIG. 4A, the formation of the drain portion 8D, the source portion 8S, gate electrode 4, and other components has been completed.

Then, referring to FIG. 4B, a cobalt film 32 is formed to cover a semiconductor substrate 1. Subsequently, the cobalt film 32 is removed from areas corresponding to the high resistance regions 30D shown in FIG. 1, so that openings 33D are formed as shown in FIG. 4C.

Then, a silicidation process is performed by a thermal treatment to form an on-drain silicide film 5D on the drain portion 8D, an on-source silicide film 5S on the source portion 8S, and an on-gate silicide film 5G on the gate electrode 4. Since the cobalt film 32, which is to be used in the silicidation process, has been removed from the opening 33D, silicidation does not occur in the opening 33D, so that the high resistance region 30D without silicide film is formed. This structure is shown in FIG. 4D.

Then, in the same manner as in Embodiment 1, an interlayer insulation film 9, drain contacts 10D, source contacts 10S, metal wires 11D and 11S, and an interlayer insulation film 12 are formed, so that an electrostatic discharge protection transistor is formed. The electrostatic discharge protection transistor has the high resistance regions 30D in the areas as shown in FIG. 1. In this case, the electrostatic discharge protection transistor of this variation may have the same structure as that of the electrostatic discharge protection transistor 50 of Embodiment 1 shown in FIG. 1 and FIGS. 2A through 2D excepting that the electrostatic discharge protection transistor of this variation does not have the protection film 31D shown in, for example, FIG. 2B. So long as there is the high resistance region 30D which has high resistance because of the absence of the on-drain silicide film 5D, current concentration is suppressed. Whether or not there is the protection film 31D does not affect the suppression of current concentration.

Alternatively, after the step illustrated with FIG. 4B, a thermal treatment may be performed to form the on-drain silicide film 5D on the whole surface of the drain portion 8D, and then part of the on-drain silicide film 5D corresponding to the high resistance region 30D may be removed. The high resistance region 30D without the on-drain silicide film 5D can also be formed in a predetermined area by removing a previously-formed silicide film instead of preventing the formation of a silicide film. In this case, the upper surface of the drain portion 8D has a recess, and the recess is filled with the interlayer insulation film 9.

### Embodiment 2

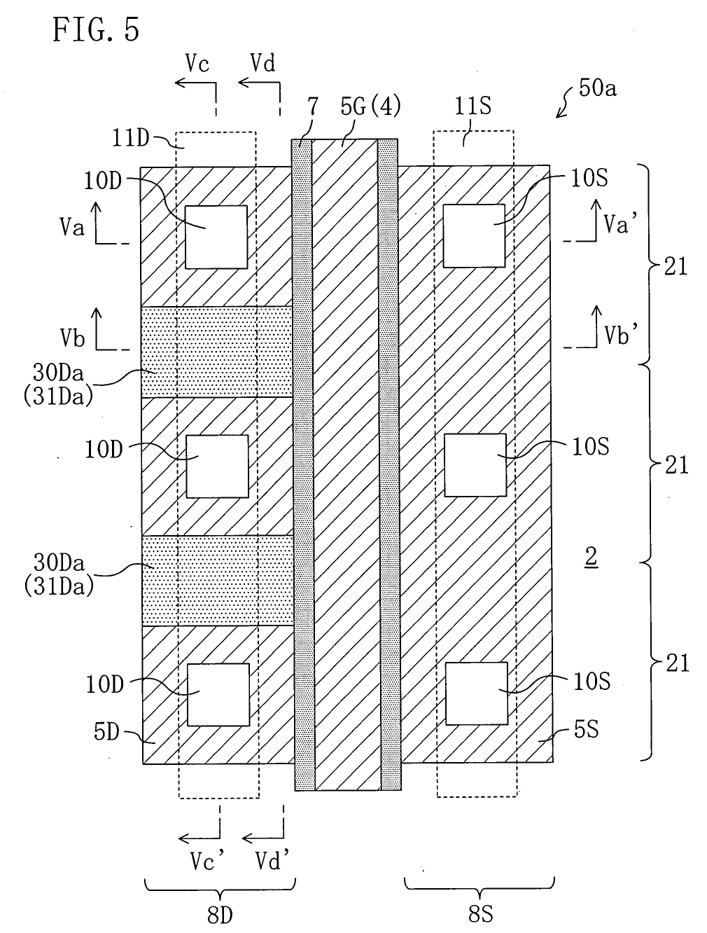

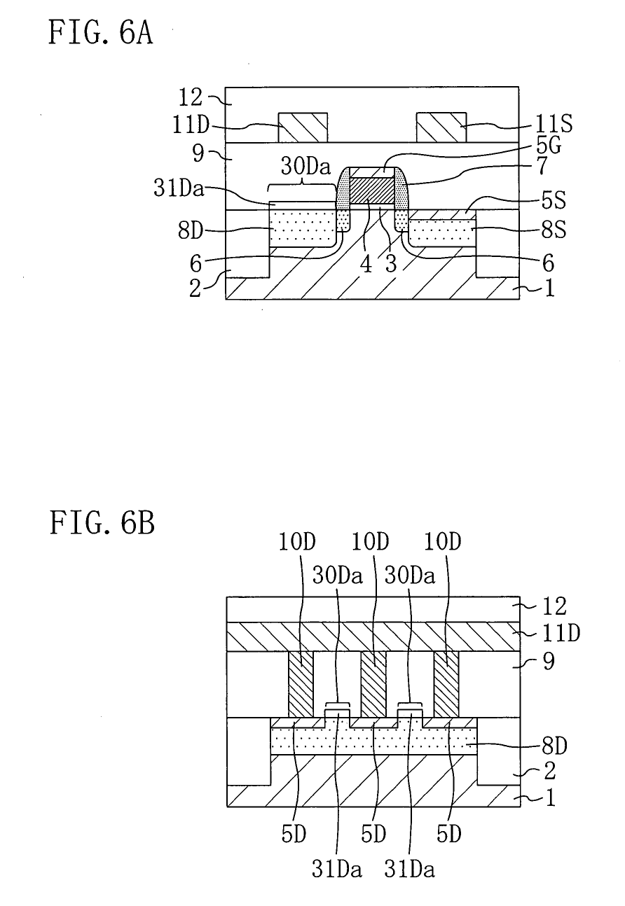

Next, a semiconductor device of Embodiment 2 of the present invention will be described with reference to the drawings. An electrostatic discharge protection transistor 50a has components corresponding to those of the electrostatic discharge protection transistor 50 of Embodiment 1 (see FIG. 1 and FIGS. 2A through 2D). In FIG. 5, FIGS. 6A and 6B referred below, substantially same components are given the same reference numerals as those of FIG. 1 and FIGS. 2A through 2D, and detailed descriptions thereof are omitted. Note that, illustration of some of the components is omitted.

FIG. 5 is a plan view illustrating a structure of the electrostatic discharge protection transistor 50a of Embodiment 2.

The electrostatic discharge protection transistor 50a of Embodiment 2 also includes a high resistance region 30Da in a drain portion 8D, wherein the high resistance region 30Da does not have an on-drain silicide film 5D (without the on-drain silicide film 5D). The area of the high resistance region 30Da is different from that of Embodiment 1.

In Embodiment 1, considering the arrangement in the gate length direction of the gate electrode 4, the high resistance region 30D is provided in an area between the gate electrode 4 and drain contacts 10D. Compared to this, in Embodiment 2, between adjacent drain contacts 10D, the high resistance region 30Da extends from a gate electrode 4 to a device isolation region 2 opposite to the gate electrode 4. In other words, in Embodiment 2, the high resistance region 30Da is provided in the same area as the high resistance region 30D of Embodiment 1, further extends into part of the drain portion 8D between the drain contacts 10D, and reaches the device isolation region 2 opposite to the gate electrode 4.

Such structure can be seen from cross sections of the electrostatic discharge protection transistor 50a. A cross section taken along the line Va-Va′ of FIG. 5 is shown in FIG. 2A. A cross section taken along the line Vb-Vb′ of FIG. 5 is shown in FIG. 6A. A cross section taken along the line Vc-Vc′ of FIG. 5 is shown in FIG. 6B. A cross section taken along the line Vd-Vd′ of FIG. 5 is shown in FIG. 2D.

That is, Embodiment 2 and Embodiment 1 are the same in terms of a cross section (taken along the line Va-Va′) in the gate length direction of each transistor structure 21 and a cross section (taken along the line Vd-Vd′) which is parallel to a gate electrode 4 and which is taken between the gate electrode 4 and the drain contacts 10D.

FIG. 6A is a cross section taken along the line Vb-Vb′ of the electrostatic discharge protection transistor 50a. FIG. 6A corresponds to FIG. 2B which is a cross section of the electrostatic discharge protection transistor 50 of Embodiment 1 excepting the area of the high resistance region. That is, a protection film 31Da is provided in an area extending from the gate electrode 4 to the device isolation region 2 opposite to the gate electrode 4, and this area is referred to as the high resistance region 30Da. FIG. 6B is a cross section taken along the line Vc-Vc′ running across the three drain contacts 10D. It can be seen in FIG. 6B that the high resistance regions 30Da are provided in areas between the drain contacts 10D, wherein the protection films 31Da are provided but the on-drain silicide films 5D are not provided in the high resistance regions 30Da.

According to the above mentioned structure, in the electrostatic discharge protection transistor 50a of Embodiment 2, it is possible to suppress the current concentration in the same manner as in Embodiment 1. That is, a flow of current is suppressed between a source contact 10D of a transistor structure 21 and a drain contact 10D of another transistor structure 21. A flow of current is not disturbed between a source contact 10S and a drain contact 10D situated to face each other with the gate electrode 4 interposed therebetween because the high resistance region 30Da is not provided in such an area that the flow of current is suppressed between the source contact 10S and the drain contact 10D situated to face each other with the gate electrode 4 interposed therebetween. Also in this connection, Embodiment 2 is the same as Embodiment 1.

Further, the high resistance region 30Da is also provided in an area between the adjacent drain contacts 10D, which produces more outstanding effects of suppressing the current concentration. Extending the high resistance region 30Da to the device isolation region 2 opposite to the gate electrode 4 is effective, but not indispensable, for more certain suppression of the current concentration.

### Embodiment 3

A semiconductor device of Embodiment 3 of the present invention will be explained below with reference to the drawings. The electrostatic discharge protection transistor 50b of Embodiment 3 is the same as the electrostatic discharge protection transistor 50 of Embodiment 1 excepting an area of a high resistance region. Therefore, explanations mainly for the high resistance region will be given below.

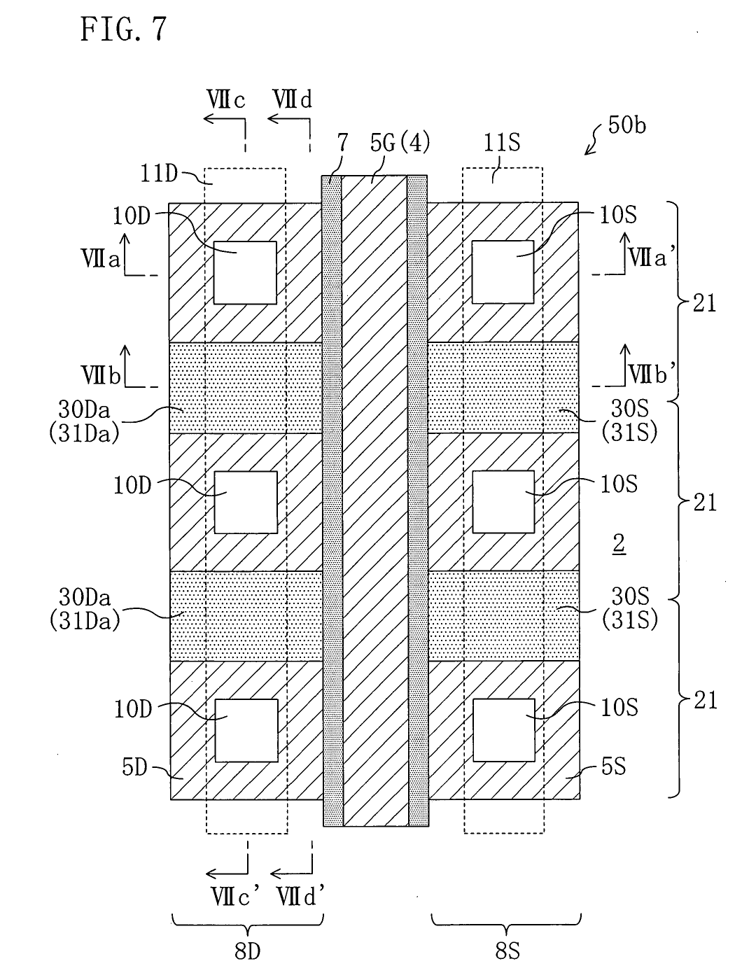

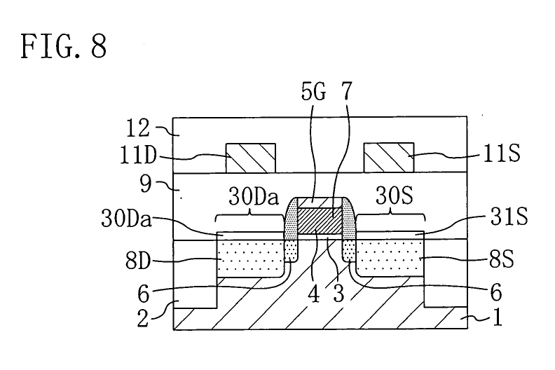

FIG. 7 is a plan view illustrating a structure of the electrostatic discharge protection transistor 50b. Compared to the electrostatic discharge protection transistor 50a of Embodiment 2 shown in FIG. 5, the structure of FIG. 7 includes high resistance regions 30S also in a source portion 8S, wherein on-source silicide films 5S are not provided in the high resistance regions 30S. FIG. 8 is a cross section taken along the line VIb-VIIb′ running between transistor structures 21. Compared to the structure of Embodiment 2 shown in FIG. 6A, it can be seen in FIG. 8 that the high resistance region 30S is also provided in the source portion 8S. That is, it can be seen in the cross section of FIG. 8 that a protection film 31S is provided but the on-source silicide film 5S is not provided on the source portion 8S. In the same manner as Embodiment 2, a cross section taken along the line VIIa-VIIa′ can be shown in FIG. 2A, a cross section taken along the line VIlc-VIIc′ can be shown in FIG. 6B, and a cross section taken along the line VIId-VIId′ can be shown in FIG. 2D.

In this way, providing the high resistance region 30S also in the source portion 8S more certainly suppresses the local current concentration in the electrostatic discharge protection transistor 50b. Note that, the high resistance region in the source portion 8S is not limited to an area extending from the gate electrode 4 to the device isolation region 2 opposite to the gate electrode 4 as shown in FIG. 7. For example, considering the arrangement in the gate length direction of the gate electrode 4, the high resistance region may be provided only in an area between the gate electrode 4 and source contacts 10S.

### Embodiment 4

A semiconductor device of Embodiment 4 of the present invention will be explained below with reference to the drawings. The electrostatic discharge protection transistor 50c of Embodiment 4 is the same as the electrostatic discharge protection transistor 50 of Embodiment 1 excepting an area of a high resistance region. Therefore, explanations mainly for the high resistance region will be given below.

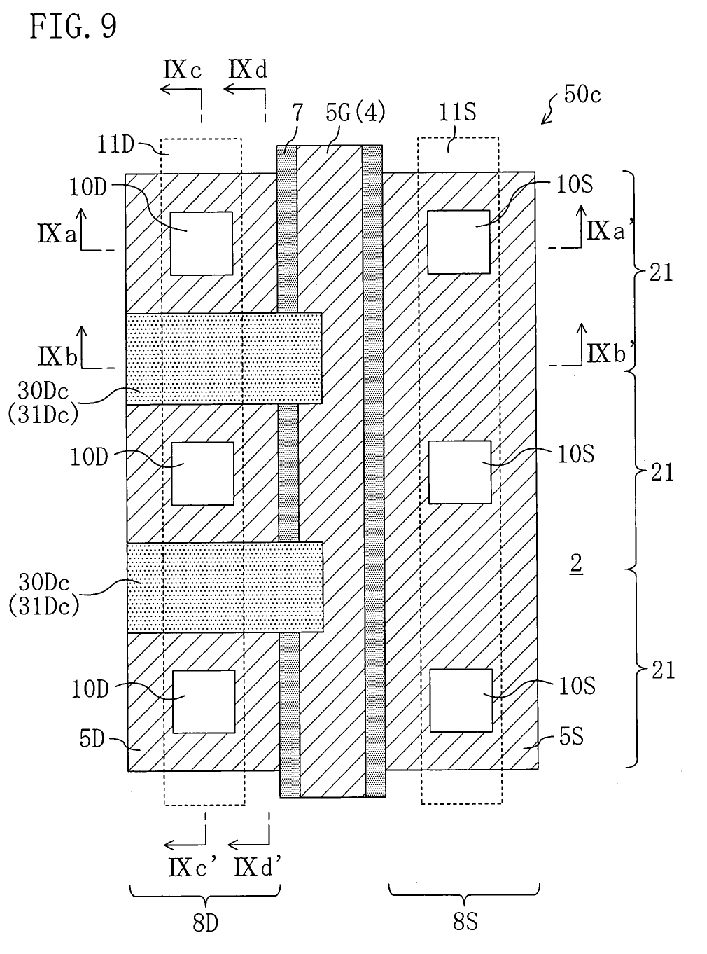

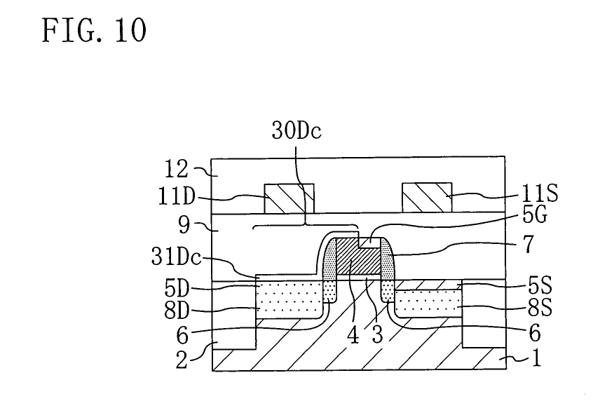

FIG. 9 is a plan view illustrating a structure of the electrostatic discharge protection transistor 50c. In this structure, the high resistance region 30Da of the electrostatic discharge protection transistor 50a of Embodiment 2 shown in FIG. 5 is further extended in a gate electrode 4. The extended high resistance region is referred to as a high resistance region 30Dc. As shown in FIG. 10 illustrating a cross section taken along the line IXb-IXb′, a protection film 31Dc is provided not only on a drain portion 8D, but also on a side wall spacer 7 and a part of the gate electrode 4. Such area having the protection film 31Dc is the high resistance region 30Dc in which silicide films (an on-drain silicide film 5D and an on-gate silicide film SG) are not provided. Note that, a silicide film is not formed in the area of the side wall spacer 7, and thus it can not say that this area has a high resistance. However, herein, an area under the protection film 31Dc, including part of the side wall spacer 7, is referred to as the high resistance region 30Dc.

An effect of the high resistance region 30Dc is to suppress the current concentration, as in the other embodiments. To this end, it is preferable that the gate electrode 4 and the high resistance region are in contact with each other, and an area in which the on-drain silicide film 5D is to be formed does not exist between the gate electrode 4 and the high resistance region. Such structure is realized by forming the protection film 31Dc in an area which straddles from the drain portion 8D to the gate electrode 4. In such structure, it is possible to certainly avoid the formation of an area in which the on-drain silicide film 5D remains between the gate electrode 4 and the high resistance region even if an area in which the protection film 31Dc is to be formed may be misaligned in a fabrication process of the electrostatic discharge protection transistor 50c.

Note that, the protection film 31Dc is formed in a case where the electrostatic discharge protection transistor 50c of Embodiment 4 is formed according to the fabrication method of the electrostatic discharge protection transistor 50 described in Embodiment 1 (see FIGS. 3A through 3E). In this case, an area in which the protection film 31D remains in FIG. 3C is modified such that the protection film 31D is also extended on the gate electrode 4.

However, it is of course possible to fabricate the electrostatic discharge protection transistor 50c according to the method described in the variation of Embodiment 1 (see FIGS. 4A through 4D). In this case, an area of the opening 33D formed in FIG. 4C is modified such that the cobalt film 32 on the gate electrode 4 is also removed. According to this method, the protection film 31Dc is not formed, but an area having a high resistance is formed in the drain portion 8D and the gate electrode 4, the silicide film being not provided in the area having a high resistance.

Alternatively, the protection film 31Dc may be formed in an area which straddles from the drain portion 8D to the side wall spacer 7 but does not extend over the gate electrode 4. In this case, the high resistance region is not formed in the gate electrode 4. Also in this structure, it is possible to realize the effect of eliminating an area in which the silicide film is provided between the high resistance region and the gate electrode.

### Embodiment 5

A semiconductor device of Embodiment 5 of the present invention will be explained below with reference to the drawings. The electrostatic discharge protection transistor 50d of Embodiment 5 is the same as the electrostatic discharge protection transistor 50 of Embodiment 1 excepting an area of a high resistance region. Therefore, explanations mainly for the high resistance region will be given below.

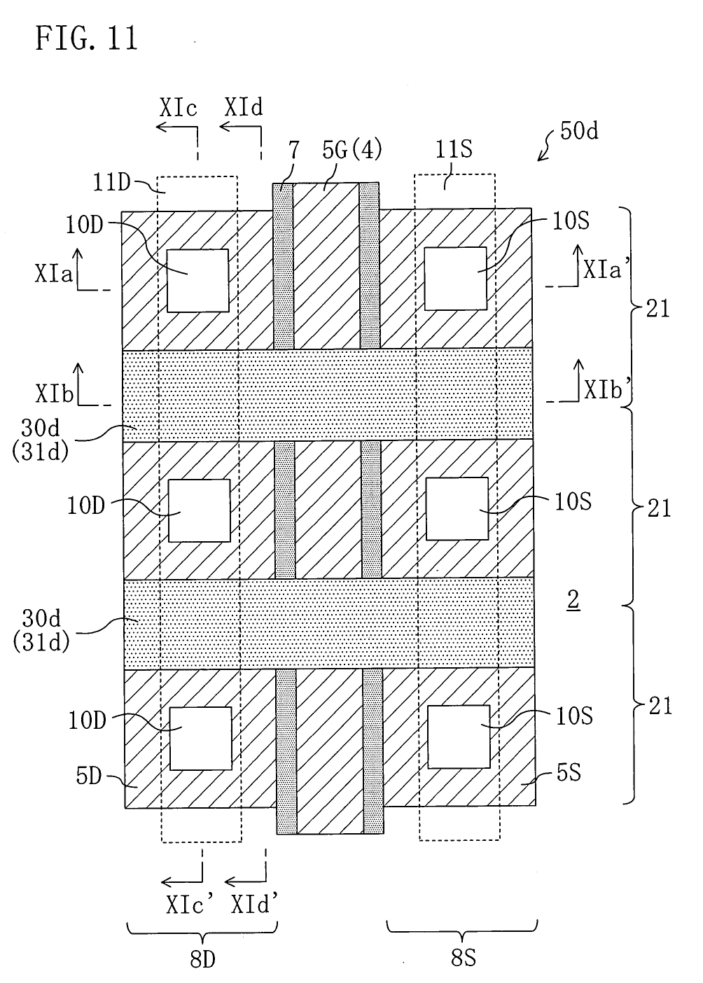

FIG. 11 is a plan view illustrating a structure of the electrostatic discharge protection transistor 50d. In FIG. 11, the high resistance regions 30Dc in the electrostatic discharge protection transistor 50c of Embodiment 4 of FIG. 9 are modified such that the high resistance regions 30Dc extend in a source portion 8S and reach a device isolation region 2 opposed to the drain portion 8D. Such modified high resistance regions are referred to as high resistance regions 30d. It is also possible to understand the structure of FIG. 11 as the structure of the electrostatic discharge protection transistor 50b of Embodiment 3 shown in FIG. 7 which is modified such that the high resistance regions 30Da and the high resistance regions 30S extend in the side wall spacers 7 and gate electrode 4 and connected with each other.

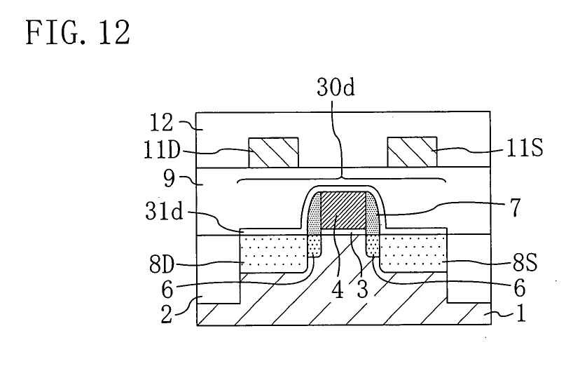

As shown in FIG. 12 illustrating a cross section taken along the line XIb-XIb′, such structure is realized by providing protection film 31d in an area which straddles from the drain portion 8D to the source portion 8S of the transistor structure 21 such that the formation of a silicide film is prevented in the area where the protection film 31d is provided. As in Embodiment 4, a silicide film is not formed in the areas of the side wall spacers 7, and thus it can not say that these areas have a high resistance. However, also in Embodiment 5, an area including parts of the side wall spacers 7 is referred to as the high resistance region 30d.

In this structure, a flow of current between a source contact 10S of a transistor structure 21 and a drain contact 10D of another transistor structure 21 is certainly suppressed. Moreover, in the structure of Embodiment 5, it is possible to avoid the formation of an area in which the silicide film remains between the gate electrode 4 and the high resistance region even if misalignment occurs in forming the protection film 31d.

Note that, the structure of Embodiment 5 may be fabricated according to the fabrication method explained with reference to the variation of Embodiment 1 instead of the fabrication method explained with reference to Embodiment 1. The structure of the electrostatic discharge protection transistor fabricated in this case is the same as the structure of the electrostatic discharge protection transistor 50d shown in FIGS. 11 and 12 excepting that the protection film 13d is not provided.

From the foregoing, in the semiconductor device of the present invention, providing a high resistance region makes it possible to suppress the current concentration and to avoid the stress caused by a device isolation region, which is a problem of the conventional technique. As a result, the leak current is reduced. Moreover, in Embodiments 2 through 5, the fabrication methods explained in Embodiment 1 and the variation thereof may be adopted. In this case, a high resistance region can be provided in a desired area by accordingly adjusting an area of the protection film or the opening to prevent the formation of the silicide film.

Embodiments 1 through 5 are explained with reference to an n-channel type transistor using a P-type semiconductor substrate. However, also in case of a p-channel type transistor, it is also possible to realize both the suppression of the current concentration and the decrease in the leak voltage by providing the high resistance region.

Three transistor structures 21 are provided in each Embodiment, but the number of the transistor structures 21 is not limited to three. Two transistor structures or four or more transistor structures may be used.

What is claimed is:

1. A semiconductor device comprising:
a gate electrode on a semiconductor substrate;
side wall spacers on side surfaces of the gate electrode;
a source portion and a drain portion in the semiconductor substrate, the source portion and the drain portion being provided laterally to the side wall spacers;
an on-source silicide film on the source portion;
an on-drain silicide film on the drain portion;
at least a pair of source contacts which are provided over the source portion such that the on-source silicide film is interposed between the source portion and the pair of source contacts and which are aligned in the gate width direction of the gate electrode; and
at least a pair of drain contacts which are provided over the drain portion such that the on-drain silicide film is interposed between the drain portion and the pair of drain contacts and which are aligned in the gate width direction of the gate electrode,
wherein part of the drain portion between the pair of drain contacts includes a high resistance region at least in an area between the side wall spacer and edges of the drain contacts facing the gate electrode such that the on-drain silicide film is not provided in the high resistance region.

2. A semiconductor device of claim 1, wherein the high resistance region extends into an area between the drain contacts.

3. A semiconductor device of claim 1, wherein the on-source silicide film is provided over the whole surface of the source portion.

4. A semiconductor device of claim 1, wherein part of the source portion between the pair of source contacts includes another high resistance region at least in an area between the side wall spacer and edges of the source contacts facing the gate electrode such that the on-source silicide film is not provided in said another high resistance region.

5. A semiconductor device of claim 4, wherein said another high resistance region extends into an area between the source contacts.

6. A semiconductor device of claim 1, further comprising an on-gate silicide film on the gate electrode, wherein the gate electrode includes an on-gate high resistance region in a part planarly continuing from the high resistance region such that the on-gate silicide film is not provided in the on-gate high resistance region.

7. A semiconductor device of claim 4, further comprising an on-gate silicide film on the gate electrode, wherein the gate electrode includes an on-gate high resistance region in a part planarly continuing from said another high resistance region such that the on-gate silicide film is not provided in the on-gate high resistance region.

8. A semiconductor device of claim 1, further comprising a protection film on the high resistance region.

9. A fabrication method of a semiconductor device comprising the steps of:
(a) forming a gate electrode on a semiconductor substrate;
(b) forming side wall spacers on side surfaces of the gate electrode;
(c) forming a source portion and a drain portion in the semiconductor substrate such that the source portion and the drain portion are provided laterally to the side wall spacers;
(d) forming an on-source silicide film on the source portion, and forming an on-drain silicide film on the drain portion; and
(e) forming at least a pair of source contacts over the source portion such that the on-source silicide film is provided between the source portion and the pair of source contacts and that the pair of source contacts are aligned in the gate width direction of the gate electrode, and forming at least a pair of drain contacts over the drain portion such that the on-drain silicide film is provided between the drain portion and the pair of drain contacts and that the pair of drain contacts are aligned in the gate width direction of the gate electrode,
wherein in step (d), in part of the drain portion between the pair of drain contacts, a high resistance region is formed at least in an area between the side wall spacer and edges of the drain contacts facing the gate electrode such that the on-drain silicide film is not provided in the high resistance region.

10. A fabrication method of claim 9, further comprising,
after step (c) and before the step (d), forming a protection film on an area of the drain portion which is to be the high resistance region,
wherein in step (d), the protection film prevents formation of the on-drain silicide film such that the high resistance region is formed.

11. A fabrication method of claim 10, wherein step (d) includes:
forming an on-gate silicide film on the gate electrode; and
forming the protection film in an area which planarly and continuously straddles from the drain portion to the gate electrode such that the high resistance region is formed in the area which planarly and continuously straddles from the drain portion to the gate electrode.

12. A fabrication method of claim 9, wherein step (d) includes:
forming a metal film on the semiconductor substrate to cover the source portion and drain portion;
removing the metal film in an area of the drain portion which is to be the high resistance region; and
performing a thermal treatment to form the on-source silicide film and the on-drain silicide film such that silicidation is prevented in the area which is to be the high resistance region.

13. A fabrication method of claim 12, wherein step (d) includes:
forming an on-gate silicide film on the gate electrode;
removing the metal film from an area which planarly and continuously straddles from the drain portion to the gate electrode such that the high resistance region is formed in the area which planarly and continuously straddles from the drain portion to the gate electrode.
